(19) United States
(12) Patent Application Publication
(10) Pub. No.: US 2007/0080466 A1
(43) Pub. Date: Apr. 12, 2007

(54) Universal chip package structure

(76) Inventors: Shih-Wen Chou, Tainan County (TW); Chun-Hung Lin, Tainan County (TW); Wu-Chang Tu, Tainan County (TW); Yu-Tang Pan, Tainan County (TW)

Correspondence Address: J.C. Patents, Inc., Suite 250, 4 Venture, Irvine, CA, 92618, US

(21) Appl. No.: 11/326,789

(22) Filed: Jan. 5, 2006

(30) Foreign Application Priority Data
Oct. 7, 2005 (TW) 94135129

(51) Int. Cl. H01L 23/52

(52) U.S. Cl. 257/777

(57) ABSTRACT

A universal chip package structure including a carrier, a chip, a plurality of bonding wires, and a molding compound is provided. The carrier has a plurality of through holes, a carrying surface, and a back surface corresponding to the carrying surface. The back surface has a plurality of contacts around the through holes. The chip with an active surface and a plurality of bonding pads on the active surface is disposed on the carrying surface. The active surface is attached to the carrying surface and the through holes expose the bonding pads. The bonding wires go through the through holes to electrically connect with the bonding pads and the contacts. In addition, the shape and size of the molding compound can be adjusted for covering the chip, the contacts, and the bonding wires.

### CROSS-REFERENCE TO RELATED APPLICATION

This application claims the priority benefit of Taiwan application serial no. 94135129, filed on Oct. 7, 2005. All disclosure of the Taiwan application is incorporated herein by reference.

### BACKGROUND OF THE INVENTION

1. Field of Invention

The present invention relates to a universal chip package structure. More particularly, the present invention relates to a universal chip package structure wherein a chip and bonding wires are protected by adjusting the shape and size of a molding compound.

2. Description of Related Art

In the semiconductor industry, the production of integrated circuits (IC) can be mainly divided into three phases: IC design, IC process and IC package. A die is fabricated after wafer manufacturing, circuit designing, mask manufacturing and wafer cutting processes. By way of a wire bonding or a flip chip bonding, a die is electrically connected to a carrier such as a leadframe or a substrate, so that bonding pads of the die can be redistributed around the die or to the underneath the active surface of the die. Take the chip package structure by wire bonding as an example. After adhered to the carrier, the die is electrically connected to the carrier by way of wire bonding. Finally, the die and the wires are covered by a molding compound to keep the die from contamination due to humidity and dust.

FIG. 1 is a schematic drawing of a conventional chip package structure. Referring to FIG. 1, the conventional chip package structure 100 includes a carrier 110, a chip 120, a plurality of bonding wires 130, and a molding compound 140, wherein the carrier 110 has a plurality of through holes 112, a carrying surface 114, and a back surface 116 corresponding to the carrying surface 114. The back surface 116 has a plurality of contacts 116a and a plurality of solder ball pads 116b, wherein the contacts 116a are disposed around the through holes 112. The chip 120 with an active surface 122 and a plurality of bonding pads 124 on the active surface 122 is disposed on the carrying surface 114, wherein the active surface 122 is attached to the carrying surface 114 through a adhesive layer 102; the foregoing through holes 112 expose the bonding pads 124. In addition, the bonding wires 130 go through the through holes 112 to electrically connect with the bonding pads 124 and the contacts 116a; the molding compound 140 covers the chip 120, the contacts 116a and the bonding wires 130.

Besides, the chip package structure 100 further includes a solder mask layer 150 and a plurality of solder balls 160, wherein the solder mask layer 150 covers the back surface 116 and has a plurality of openings 150a exposing the contacts 116a and the solder ball pads 116b; the solder balls 160 are electrically connected to the solder ball pads 116b.

As mentioned above, the conventional chip package structure is applied to the current market products such as Dynamic Random Access Memory (DRAM) which has multiple package modes and multiple package sizes according to brands or design, or multiple chip sizes and multiple layouts for bonding pads and circuit on chips according to chip manufacturing technology. Accordingly, to incorporate the chip package structures in the above multiple design modes, carriers and mold chase (not shown) have to be redesigned to perform package process. For example, the locations of through holes of carriers have to be adjusted according to the arrangements of chips. Thus, the manufacturing cost of the chip package and the expense for manufacturing, storing and administrating the mold chase are increased.

### SUMMARY OF THE INVENTION

Accordingly, the present invention is directed to provide a universal chip package structure adapted for the chip package structures with multiple package modes, multiple package or chip sizes, or multiple layouts for bonding pads and circuit on chips.

For achieving the above or other objectives, the present invention provides a universal chip package structure including a carrier, a chip, a plurality of bonding wires, and a molding compound. The carrier has a plurality of through holes, a carrying surface, and a back surface corresponding to the carrying surface, wherein the back surface has a plurality of contacts around the through holes and a plurality of solder ball pads. The chip with an active surface and a plurality of bonding pads on the active surface is disposed on the carrying surface, wherein the active surface is attached to the carrying surface and the foregoing through holes expose the bonding pads. The bonding wires go through the through holes to electrically connect with the bonding pads and the contacts. In addition, the molding compound for covering the chip, the contacts and the bonding wires has a first area and a second area, wherein the first area fills the through holes while the second area covers the back surface and is connected with the first area.

According to a preferred embodiment of the present invention, the universal chip package structure further includes a solder mask layer covering the back surface and having a plurality of openings, wherein the openings expose a plurality of contacts and a plurality of solder ball pads. In addition, the universal chip package structure further includes, for example, a plurality of solder balls electrically connected to the solder ball pads.

In an embodiment of the present invention, the bonding wires are electrically connected with the bonding pads and the contacts by way of wire bonding.

In an embodiment of the present invention, the bonding wires are electrically connected with the bonding pads and the contacts by way of reverse wire bonding.

In an embodiment of the present invention, the material of the bonding wires is gold, for example.

For achieving the above objectives, the present invention provides another universal chip package structure including a carrier, a chip, a plurality of bonding wires and a molding compound. The carrier has a first solder mask layer, a plurality of through holes, a carrying surface, and a back surface corresponding to the carrying surface, wherein the back surface has a plurality of contacts around the through holes and a plurality of solder ball pads. The first solder mask layer covers the back surface and has a plurality of openings exposing the contacts and solder ball pads. The chip with an active surface and a plurality of bonding pads on the active surface is disposed on the carrying surface, wherein the active surface is attached to the carrying surface and the foregoing through holes expose the bonding pads.

As mentioned above, the bonding wires go through the through holes to electrically connect with the bonding pads and the contacts. In addition, covering the chip, the contacts and the bonding wires, the molding compound fills the through holes and openings connected with the through holes, wherein the surface of the molding compound is aligned with the surface of the first solder mask layer.

In an embodiment of the present invention, the universal chip package structure further includes for example a plurality of solder balls electrically connected to the solder ball pads.

In an embodiment of the present invention, the bonding wires are electrically connected with the bonding pads and contacts by way of reverse wire bonding.

In an embodiment of the present invention, the material of the bonding wires is gold, for example.

In an embodiment of the present invention, the carrier further includes a second solder mask layer covering the carrying surface of the carrier.

In an embodiment of the present invention, the thickness of the first solder mask layer is for example more than or equal to the thickness of the second solder mask layer.

In an embodiment of the present invention, the thickness of the first solder mask layer is for example more than the wire bonding height of the bonding wires.

In an embodiment of the present invention, the thickness of the first solder mask layer is between 25 micron to 400 micron.

Based on the above, in the universal chip package structure of the present invention, the shape and size of the molding compound are adjusted for covering the chip and the bonding wires by changing the shape of the carrier but without changing the mold chase. Wherein, the universal chip package structure can be used to the chip package structures with multiple package modes, multiple package or chip sizes, or multiple layouts for bonding pads and circuit on chips.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a schematic drawing of a conventional chip package structure.

FIG. 2A is a schematic drawing of a universal chip package structure of a preferred embodiment of the present invention.

FIG. 2B is an enlarged schematic drawing of the area R in FIG. 2A.

FIG. 3 is a schematic drawing of another universal chip package structure of a preferred embodiment of the present invention.

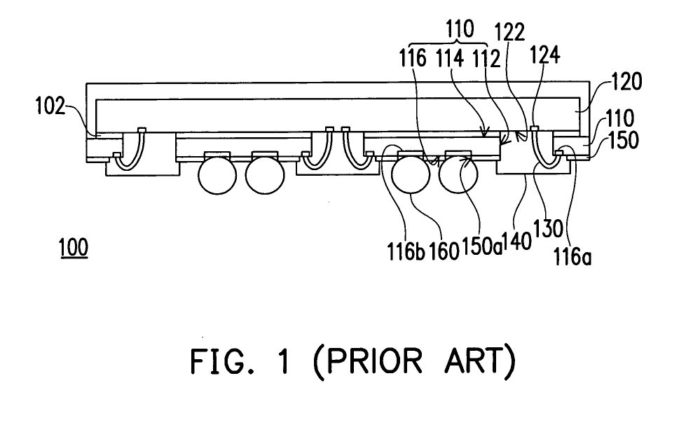

### DESCRIPTION OF EMBODIMENTS

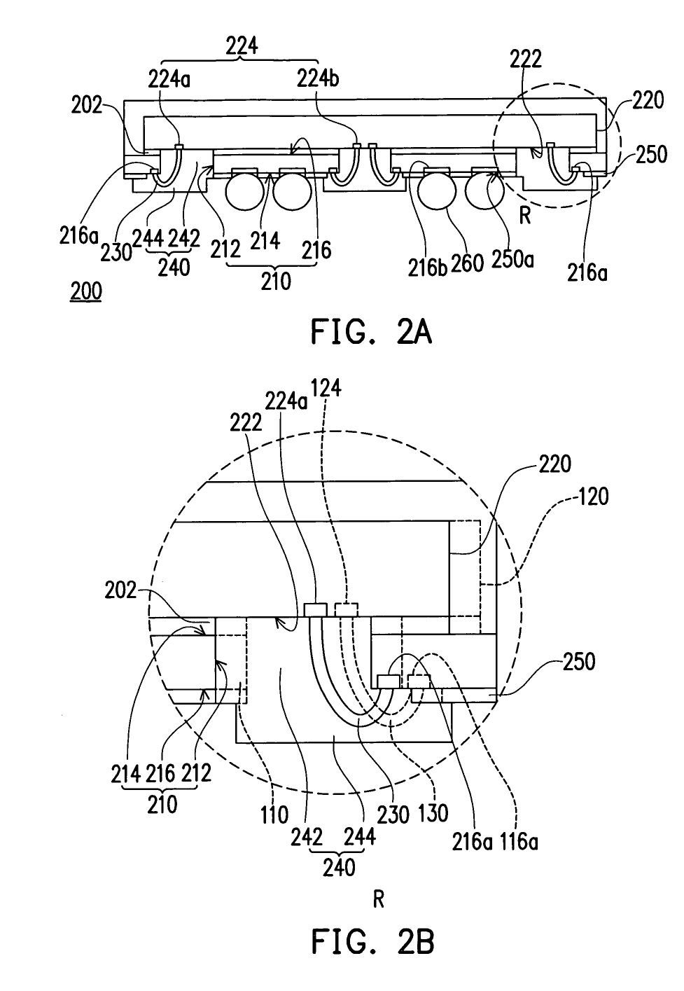

FIG. 2A is a schematic drawing of a universal chip package structure of a preferred embodiment of the present invention. Referring to FIG. 2A, the universal chip package structure 200 includes a carrier 210, a chip 220, a plurality of bonding wires 230 and a molding compound 240. In the present embodiment, the carrier 210 is a substrate, such as a PCB substrate with a plurality of through holes 212, a carrying surface 214 and a back surface 216 corresponding to the carrying surface 214, wherein on the back surface 216, a plurality of contacts 216a and a plurality of solder ball pads 216b are disposed and connected with each other, wherein the contacts 216a are located around the through holes 212. In addition, the chip 220 with an active surface 222 and a plurality of bonding pads 224 is disposed on the carrying surface 214, wherein the bonding pads 224 are disposed on the active surface 222 and include, for example, peripheral pads 224a and central pads 224b according to the distribution areas.

As mentioned above, the active surface 222 is attached to the carrying surface 214 through, for example, a adhesive layer 202. A plurality of through holes 212 expose parts of the active surface 222, wherein the parts of the active surface 222 are the areas with the bonding pads 224; namely, the through holes 212 expose the bonding pads 224. Besides, the bonding wires 230 go through the through holes 212 to electrically connect with the bonding pads 224 on the active surface 222 and the contacts 216a on the back surface 216. In the present embodiment, the bonding wires 230 are electrically connected with the bonding pads 224 and contacts 216a by way of, for example, wire bonding or reverse wire bonding, wherein reverse wire bonding can decrease the wire bonding height; the material of the bonding wires 230 is gold, for example. The molding compound 240 is adapted for covering the chip 220, the contacts 216a and bonding wires 230 to keep the above components from damages or contamination due to humidity and dust pollution.

In order to better understand the difference between the universal chip package structure 200 of the present invention and the conventional chip package structure 100, a further description is given below. FIG. 2B is an enlarged schematic drawing of the area R in FIG. 2A. Referring to FIG. 2B, the molding compound 240 of the present invention has a first area 242 and a second area 244, wherein the first area 242 fills the through holes while the second area 244 covers the back surface 216 and is connected with the first area 242. In detail, the first area 242 covers parts of the bonding wires 230 in the through holes 212 and the bonding pads 224a exposed by the through holes 212; the second area 244 covers the contacts 216a and parts of the bonding wires 230 outside the through holes 212. Note that even with different package sizes, the molding compound 240 of the present invention can protect the chip, the contacts and the bonding wires. Naturally, the molding compound 240 of the present invention is also adapted for the conventional chip package structure 100; namely, the molding compound 240 of the present invention can also cover the bonding pads 124, the contacts 116a, and the bonding wires 130 to keep the above components from damages or contamination due to humidity and dust. In addition, so long as the part of the bonding wires 230 protruding from the through holes 212 is covered, the present invention does not limit the area where the second area 244 and the first area 242 are connected.

It is known from above that according to the universal chip package structure 200 of the present invention, it is not necessary to develop a new mold chase for performing the molding process with multiple package sizes; that is, without changing the second area 244 of the molding compound 240, the first area 242 can be changed in size and location according to the size and layout of the chip 220, so that the universal chip package structure 200 can be used to the chip package structures with multiple package modes, multiple package or chip sizes, or multiple layouts for bonding pads and circuit on chips, and has the function of protecting the chip 220, the contacts 216a and the bonding wires 230. Thus, the manufacturing cost of chip package structures can be reduced and the expense for manufacturing, storing and administrating the mold chase can also be saved.

Referring to FIG. 2A again, the universal chip package structure 200 further includes for example a solder mask layer 250. For instance, the solder mask layer 250 covers the back surface 216 and has a plurality of openings 250a exposing the contacts 216a and a plurality of solder ball pads 216b. Corresponding to the aforementioned solder ball pads 216b, the universal chip package structure 200 also includes a plurality of solder balls 260 which are electrically connected with the solder ball pads 216b exposed by the openings 250a.

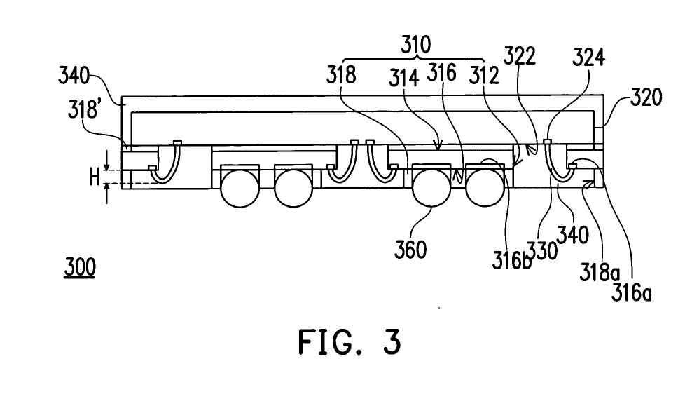

FIG. 3 is a schematic drawing of another universal chip package structure of a preferred embodiment of the present invention. From FIG. 3, it is known that the universal chip package structure of the present embodiment is very similar to that of the aforementioned embodiment. The main difference is that the shape and arrangement of the molding compound on the back surface of the universal chip package structure of the present embodiment, which is described in detail below.

Similar to the universal chip package structure 200 of the aforementioned embodiment, the universal chip package structure 300 of the present embodiment includes a carrier 310, a chip 320, a plurality of bonding wires 330 and a molding compound 340. The carrier 310 has a plurality of through holes 312, a carrying surface 314, a back surface 316 corresponding to the carrying surface 314, and a first solder mask layer 318. The back surface 316 has a plurality of contacts 316a and a plurality of solder ball pads 316b, wherein the contacts 316a lie around the through holes 312. The first solder mask layer 318 covers the back surface 316 and has a plurality of openings 318a which expose the contacts 316a and a plurality of solder ball pads 316b. The layout of the chip 320 and the bonding wires 330 is the same as that of the chip 220 and the bonding wires 230 in the aforementioned embodiment, so are not repeated here.

As mentioned above, the molding compound 340 of the present embodiment is also adapted for covering the bonding pads 324, the contacts 316a and the bonding wires 330. Note that the molding compound 340 fills the through holes 312 and the openings 318a connected with the through holes 312, and the surface of the molding compound 340 is aligned with the surface of the first solder mask layer 318. On the other hand, the carrier 310 can also include a second solder mask layer 318′ which covers the carrying surface 314 of the carrier 310. In the present embodiment, the thickness of the first solder mask layer 318 is for example more than the thickness of the second solder mask layer 318′, or the thickness of the first solder mask layer 318 is more than the wire bonding height H of the bonding wires 330, wherein the thickness of the first solder mask layer 318 is for example between 25 micron to 400 micron. Of course, the thickness of the first solder mask layer 318 can also be equal to the thickness of the second solder mask layer 318′ under a critical condition that the thickness of the first solder mask layer 318 is more than the wire bonding height H of the bonding wires 330.

It is known from above that when performing the molding process for the universal chip package structure 300 of the present embodiment, only a mold chase with a smooth surface (not shown) is needed for the molding compound 340 to cover the bonding pads 324, the contacts 316a and the bonding wires 330 to protect the above components. Therefore, in the universal chip package structure 300 of the present embodiment, it is not necessary to develop a new mold chase for performing the molding process with multiple package sizes. Naturally, the universal chip package structure 300 of the present embodiment has the same advantages as the aforementioned universal chip package structure 200.

In addition, the universal chip package structure 300 also includes a plurality of solder balls 360 which are electrically connected with the solder ball pads 316b exposed by the openings 318a. On the other hand, the bonding wires 330 are electrically connected with the bonding pads 324 on the active surface 322 and contacts 216a on the back surface 316 by way of, for example, wire bonding or reverse wire bonding, wherein the material of the bonding wires 330 is gold, for example.

In summary, compared with the conventional technology, the universal chip package structure of the present invention has the following advantages:

(1) The universal chip package structure of the present invention is adapted for the chip package structures with multiple package modes, multiple package or chip sizes, or multiple layouts for bonding pads and circuit on chips, so that the manufacturing cost of chip package structures can be reduced.

(2) The expense for manufacturing, storing and administrating the mold chase can be saved.

The present invention is disclosed above with its preferred embodiments. It is to be understood that the preferred embodiment of present invention is not to be taken in a limiting sense. It will be apparent to those skilled in the art that various modifications and variations can be made to the structure of the present invention without departing from the scope or spirit of the invention. The protection scope of the present invention is in accordant with the scope of the following claims and their equivalents.

What is claimed is:

1. A universal chip package structure, comprising:
a carrier, having a plurality of through holes, a carrying surface, and a back surface corresponding to the carrying surface, wherein the back surface has a plurality of contacts around the through holes and a plurality of solder ball pads;
a chip, disposed on the carrying surface, having an active surface and a plurality of bonding pads on the active surface, wherein the active surface is attached to the carrying surface and the through holes expose the bonding pads;
a plurality of bonding wires, going through the through holes to electrically connect with the bonding pads and the contacts; and
a molding compound, adapted for covering the chip, the contacts and the bonding wires, having a first area and a second area, wherein the first area fills the through holes; the second area covers the back surface and is connected with the first area.

2. The universal chip package structure as claimed in claim 1, further comprising a solder mask layer covering the back surface and having a plurality of openings.

3. The universal chip package structure as claimed in claim 2, wherein the openings expose the contacts and the solder ball pads.

4. The universal chip package structure as claimed in claim 3, further comprising a plurality of solder balls electrically connected to the solder ball pads.

5. The universal chip package structure as claimed in claim 1, wherein the bonding wires are electrically connected with the bonding pads and the contacts by way of reverse wire bonding.

6. The universal chip package structure as claimed in claim 1, wherein the material of the bonding wires comprises gold.

7. A universal chip package structure, comprising:
a carrier, having a first solder mask layer, a plurality of through holes, a carrying surface, and a back surface corresponding to the carrying surface, wherein the back surface has a plurality of contacts around the through holes and a plurality of solder ball pads; the first solder mask layer covers the back surface and has a plurality of openings exposing the contacts and the solder ball pads;
a chip, disposed on the carrying surface, having an active surface and a plurality of bonding pads on the active surface, wherein the active surface is attached to the carrying surface; the through holes expose the bonding pads;
a plurality of bonding wires, going through the through holes to electrically connect with the bonding pads and the contacts; and
a molding compound, adapted for covering the chip, the contacts and the bonding wires, filling the through holes and openings connected with the through holes, wherein the surface of the molding compound is aligned with the surface of the first solder mask layer.

8. The universal chip package structure as claimed in claim 7, further comprising a plurality of solder balls electrically connected to the solder ball pads.

9. The universal chip package structure as claimed in claim 7, wherein the bonding wires are electrically connected with the bonding pads and the contacts by way of reverse wire bonding.

10. The universal chip package structure as claimed in claim 7, wherein the material of the bonding wires comprises gold.

11. The universal chip package structure as claimed in claim 7, wherein the carrier further comprises a second solder mask layer covering the carrying surface.

12. The universal chip package structure as claimed in claim 11, wherein the thickness of the first solder mask layer is more than or equal to the thickness of the second solder mask layer.

13. The universal chip package structure as claimed in claim 7, wherein the thickness of the first solder mask layer is more than the wire bonding height of the bonding wires.

14. The universal chip package structure as claimed in claim 7, wherein the thickness of the first solder mask layer is between 25 micron and 400 micron.
